(19) United States
(12) Patent Application Publication
(10) Pub. No.: US 2025/0259806 A1
(43) Pub. Date: Aug. 14, 2025

(54) POWER SWITCH AND METHOD FOR CONTROLLING OPERATIONAL STATES OF ELECTRICAL LOADS

(71) Applicant: HONEYWELL INTERNATIONAL INC., Charlotte, NC (US)

(72) Inventors: Hari Suriya REDDY, Charlotte, NC (US); Hussain -, Charlotte, NC (US); Satamanyu DASH, Charlotte, NC (US)

(21) Appl. No.: 19/041,052

(22) Filed: Jan. 30, 2025

(30) Foreign Application Priority Data
Feb. 14, 2024 (IN) 202411010196

(51) Int. Cl. H01H 13/14; H01H 13/20

(52) U.S. Cl. CPC H01H 13/14; H01H 13/20; H01H 2219/06; H01H 2219/062

(57) ABSTRACT

A power switch is disclosed. The power switch comprises at least one photodetector/infrared (IR)/optical sensor configured to emit one or more rays. The power switch further comprises at least one plunger configured to move from a first position to a second position. Further, in an instance in which the at least one plunger is in second position, the at least one plunger is configured to interrupt/block, or reflect back the emitted one or more rays to the at least one sensor. Further, at least one switching circuit is electrically connected to the at least one sensor. Further, the at least one sensor is configured to detect the reflected one or more rays from the at least one plunger to generate one or more signals. Thereafter, the at least one switching circuit is configured to open or close the power switch based at least on the generated one or more signals.

### CROSS-REFERENCE TO RELATED APPLICATION

This application claims priority pursuant to 35 U.S.C. 119 (a) to Indian Application No. 202411010196, filed Feb. 14, 2024, which application is incorporated herein by reference in its entirety.

### BACKGROUND

Electromechanical (EM) basic switches are the most commonly used type of switches for making or breaking circuits. The EM basic switches play a crucial role in controlling the flow of current across various electronic devices. Despite being used across the world, EM switches have multiple limitations and are gradually being replaced by non-contact switches. The non-contact switches are based on Hall based or Anisotropic Magneto Resistance (AMR) based technology to eliminate the need for direct physical contact. The lack of any direct physical contact enhances the reliability and durability of switches. Durability is important, especially in devices that require frequent switching. The non-contact switches also require less maintenance and reduce the risk of malfunction to give an edge over basic electromechanically switches, especially in dust and corrosive settings. However, after many observations, the non-contact switches face multiple challenges while handling higher current. While being proficient with lower currents, generally in milliampere (mA), the non-contact switches face limitations with currents exceeding 1 Ampere (A). Consequently, in the market of high current settings, the EM basic switches are the only option available, and are not suitable for future generation requirements such as data collection, switch failure detection, and switch life monitoring.

The inventors have identified numerous areas of improvement in the existing technologies and processes, which are the subjects of embodiments described herein. Through applied effort, ingenuity, and innovation, many of these deficiencies, challenges, and problems have been solved by developing solutions that are included in embodiments of the present disclosure, some examples of which are described in detail herein.

### BRIEF SUMMARY

The following presents a summary of some example embodiments to provide a basic understanding of some aspects of the present disclosure. This summary is not an extensive overview and is intended to neither identify key or critical elements nor delineate the scope of such elements. It will also be appreciated that the scope of the disclosure encompasses many potential embodiments in addition to those here summarized, some of which will be further described in the detailed description that is presented later.

In an example embodiment, a power switch is disclosed. The power switch comprises at least one sensor configured to emit one or more rays and at least one plunger configured to move from a first position to a second position. In an instance in which the at least one plunger is in the second position, the at least one plunger is configured to interrupt and reflect back the emitted one or more rays to the at least one sensor. The power switch further comprises at least one switching circuit electrically connected to the at least one sensor. The at least one sensor is configured to detect the reflected one or more rays from the at least one plunger to generate one or more signals. Thereafter, the at least one switching circuit is configured to open or close the power switch based at least on the generated one or more signals.

In some embodiments, the at least one plunger is configured to block or scatter at least a portion of the one or more rays when the at least one plunger is in the second position. In some embodiments, the at least one plunger is positioned over at least one biasing member. In some embodiments, the at least one biasing member is configured to provide an operating force to the at least one plunger to allow translational movement of the at least one plunger. In some embodiments, the at least one plunger is coated with a reflective material that is configured to reflect or scatter the emitted one or more rays back to the at least one sensor.

In some embodiments, the at least one plunger is positioned in proximity to the at least one sensor. Further, the translational movement of the at least one plunger facilitates to interrupt and reflect back the emitted one or more rays to the at least one sensor for opening or closing the power switch. In some embodiments, the at least one sensor comprises at least one of a photodetector, an Infrared (IR) sensor, or an optical sensor.

In some embodiments, the at least one switching circuit comprises one or more transistors that upon receiving the one or more signals from the at least one sensor, open or close the power switch. In some embodiments, the one or more transistors comprises at least one of a metal oxide field-effect transistor (MOSFET), a field-effect transistor (FET), an insulated-gate bipolar transistor (IGBT), or any power switching device.

In some embodiments, the at least one switching circuit is isolated from one or more electrical loads via at least one isolated gate driver to keep the power switch separated from the one or more electrical loads. In some embodiments, at least one power source is configured to supply power to the one or more electrical loads.

In some embodiments, the at least one sensor and the at least one switching circuit are fabricated over a printed circuit board (PCB).

In another example embodiment, a method is disclosed. The method comprises steps of emitting, via at least one sensor, one or more rays; interrupting and reflecting, via at least one plunger configured to move from a first position to a second position, the emitted one or more rays in an instance in which the at least one plunger is in the second position; and receiving, via at least one switching circuit electrically connected to the at least one sensor, one or more signals generated by the at least one sensor, upon receiving the reflected one or more rays, to open or close the power switch.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the present disclosure in any way. It will be appreciated that the scope of the present disclosure encompasses many potential embodiments in addition to those here summarized, some of which will be further described below.

### BRIEF DESCRIPTION OF THE DRAWINGS

Having thus described certain example embodiments of the present disclosure in general terms, reference will hereinafter be made to the accompanying drawings, which are not necessarily drawn to scale, and wherein:

FIG. 1A illustrates a side view of a power switch in accordance with an example embodiment of the present disclosure;

FIG. 1B illustrates a sectional view of the power switch in accordance with an example embodiment of the present disclosure;

FIG. 2A illustrates a block diagram of the power switch in accordance with an example embodiment of the present disclosure;

FIG. 2B illustrates a flow diagram of the power switch in accordance with an example embodiment of the present disclosure; and,

FIG. 3 illustrates a flowchart showing steps of a method for controlling operational states of electrical loads using the power switch in accordance with an example embodiment of the present disclosure.

### DETAILED DESCRIPTION

Some embodiments will now be described more fully hereinafter with reference to the accompanying drawings, in which some, but not all, embodiments of the present disclosure are shown. Indeed, various embodiments may be embodied in many different forms and should not be construed as limited to the embodiments set forth herein; rather, these embodiments are provided so that this disclosure will satisfy applicable legal requirements.

The components illustrated in the figures represent components that may or may not be present in various embodiments of the present disclosure described herein such that embodiments may include fewer or more components than those shown in the figures while not departing from the scope of the present disclosure. Some components may be omitted from one or more figures or shown in dashed line for visibility of the underlying components.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in various embodiments,” “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

The present disclosure provides various embodiments of a power switch, and methods for controlling operational states of one or more electrical loads using a non-contact based power switch. Embodiments may be configured to emit one or more rays using at least one sensor. Embodiments may be configured to interrupt and reflect back the emitted one or more rays, to the at least one sensor using at least one plunger. Embodiments may be configured to detect the reflected one or more rays from the at least one plunger to generate one or more signals. Embodiments may be configured to open or close the power switch based at least on the generated one or more signals. Embodiments may provide a safe, precise, and versatile way to control one or more electric loads without any physical contact with the power switch. Embodiments may provide an alternative way to replace mechanical actuators to avoid any wear and tear, thereby increasing the life span of the power switch.

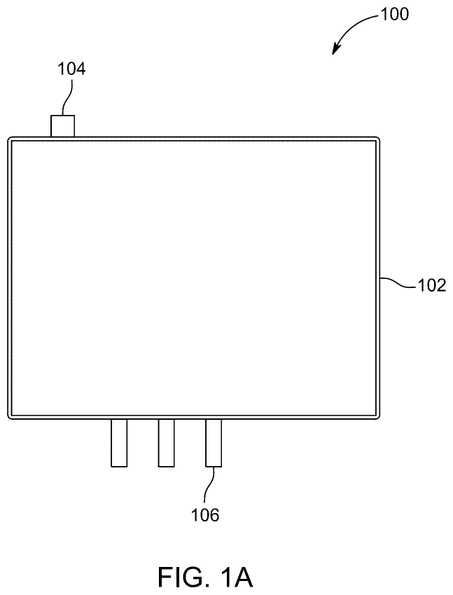

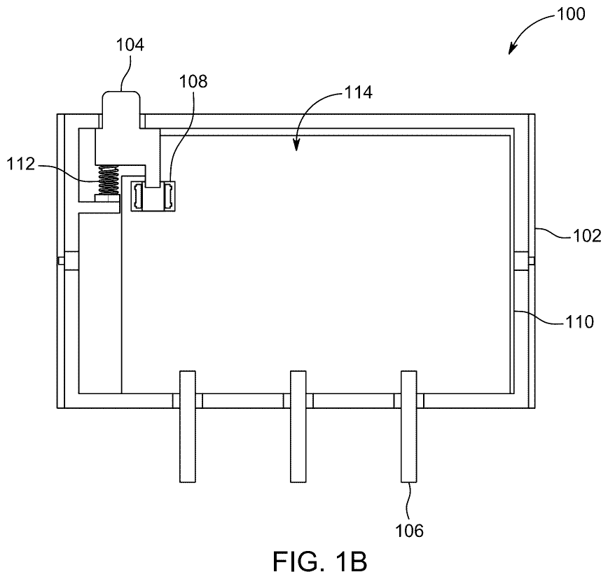

FIG. 1A illustrates a side view of a power switch 100, in accordance with an example embodiment of the present disclosure.

The power switch 100 may comprise a housing 102, at least one plunger 104, and one or more terminals 106. Each plunger 104 and each terminal 106 may be positioned at least partially within the housing 102. In some embodiments, the housing 102 may be constructed from a group of durable materials such as, but is not limited to, metals, plastic, or alloys. The durable materials may be selected from the group of durable materials due to their durability and resistance to heat, wear, and tear. Further, design of the housing 102 may be selected from one or more shapes that is easy to use. In some example embodiments, the one or more shapes may include a cuboidal shape, a cubical shape, or any other shape known in the art.

In some embodiments, at least one plunger 104 may be partially enclosed within the housing 102. In some embodiments, at least one plunger 104 may be configured to move from a first position, as depicted in FIG. 1B, to a second position (not shown) upon application of a sufficient external force. Further, the first position may correspond to an upward position. Further, the second position may correspond to a downward position. In some embodiments, the application of a sufficient external force over at least one plunger 104 may cause a change of the state of the power switch 100. The state of power switch 100 may change from an open state to a closed state, and vice-versa. Further, at least one plunger 104 may be constructed from a group of materials including at least one of metal, plastic, rubber, and the like, as per the application of the external force, sensitivity, and environmental conditions. Further, at least one plunger 104 may be coated with specific sealants for preventing any accumulation of dust and moisture over at least one plunger 104 during the prolonged use of at least one plunger 104.

In some embodiments, one or more terminals 106 may be electrically coupled with various other components of the power switch 100. In some exemplary embodiments, the one or more terminals 106 may allow coupling between a power source (not shown), and a resistive, capacitive, lamp, motor or inductive load (not shown). In some embodiments, the one or more terminals 106 act as a gateway for electricity to flow, control the path of the electricity, and also determine the function of the power switch 100. Further, the one or more terminals 106 may be crafted using high quality materials with low resistive properties such as copper, aluminum, brass and alike, for ensuring efficient current transfer without any energy loss minimizing heat generation.

FIG. 1B illustrates a sectional view of the power switch 100, in accordance with an example embodiment of the present disclosure. FIG. 1B is described in conjunction with FIG. 1A.

The power switch 100 may further comprise at least one sensor 108, a printed circuit board (PCB) 110, at least one biasing member 112, such as a spring, and at least one switching circuit 114. At least one switching circuit 114 may be fabricated over the PCB 110, which may be encased inside the housing 102. In some embodiments, the at least one plunger 104 may be positioned over the at least one biasing member 112.

In some embodiments, at least one sensor 108 may be configured to emit one or more rays. In some embodiments, at least one sensor 108 may be encased within housing 102. Further, at least one sensor 108 may be positioned in proximity to at least one plunger 104. At least one sensor 108 may comprise an emitter (not shown). The emitter may be configured to emit one or more infrared (IR) signals in a field of view (FOV) (not shown) of at least one sensor 108. In some embodiments, at least one sensor 108 may further comprise a receiver (not shown). The receiver may be configured to receive the one or more IR signals after bouncing back from a target surface.

In some embodiments, the application of the sufficient external force on at least one plunger 104 may result in a translational movement of at least one plunger 104. Further, in an instance in which at least one plunger 104 is in the second position, at least one plunger 104 may be configured to interrupt and reflect back the emitted one or more rays to at least one sensor 108. Further, the receiver may detect interruption caused by at least one plunger 104 to generate one or more signals as an output response by at least one sensor 108. The resulting output response may provide an operating force for opening or closing power switch 100. In some example embodiments, the opening of power switch 100 may allow supplying of power from the power source to the resistive or inductive load. Further, the closing of power switch 100 may stop supply of power from the power source to the resistive or inductive load.

In various embodiments, at least one sensor 108 may comprise at least one of a photodetector, infrared (IR) sensor, or an optical sensor that emits photodetector rays, IR rays, or optical rays respectively around at least one sensor 108. In some example embodiments, at least one sensor 108 may be the photodetector, which may be sensitive to visible light ranging in between 400-700 nanometer (nm) wavelength. The translational movement of at least one plunger 104 may block or reduce the intensity of light received by the receiver of at least one sensor 108. The photodetector, based on the reduced intensity of light, may generate an output response. The generated output response may further result in opening or closing power switch 100.

In another example embodiment, at least one sensor 108 may correspond to at least one of the IR sensor that may be sensitive to infrared radiation, specifically in between 700 nm to 1 millimeter (mm) wavelength. The IR sensor may emit IR rays that may be received by the receiver. Therefore, translational movement of at least one plunger 104 may physically break the path of the emitted IR rays, received by the receiver. The IR sensor, based on the sudden drop in detected IR radiation may generate an output response. The generated output response may further result in opening and closing of power switch 100.

In yet another example embodiment, at least one sensor 108 may correspond to the optical sensor. Further, the optical sensor may emit optical rays that may be received by the receiver. Further, the translational movement of at least one plunger 104 may physically break the path of emitted optical rays, received by the receiver, causing a detected change in the optical sensor. Further, based on the detected change, the optical sensor may generate an output response. The generated output response may further result in opening or closing power switch 100.

In some embodiments, at least one plunger 104 may be coated with a reflective material that may be configured to reflect or scatter the emitted one or more rays back to at least one sensor 108. In some embodiments, the reflective material may inherit properties that may completely or partially reflect the emitted one or more rays back to the receiver only after application of the external force on at least one plunger 104. Further, in an instance in which at least one plunger 104 may be in the second position, at least one plunger 104 may be configured to block or scatter at least a portion of the one or more rays.

In some embodiments, at least one sensor 108 and the at least one switching circuit 114 may be fabricated on PCB 110. PCB 110 may facilitate connecting one or more electrical or electronic components present within the power switch 100. In some exemplary embodiments, the PCB 110 may comprise of one or more conductive and insulated layers. The one or more conductive and insulated layers may be configured to allow connection between the one or more electrical or electronic components fabricated on PCB 110. In some exemplary embodiments, the PCB 110 may be constructed with a group of materials including at least fiberglass or ceramics having multiple metallic tracks, e.g., copper tracks, for electric connections.

As illustrated in FIG. 1B, power switch 100 may comprise the at least one biasing member 112. At least one biasing member 112 may be configured as a spring, such as a helical spring, and may be spiraled around at least one plunger 104. At least one biasing member 112 may exhibit a compressive force for placing at least one plunger 104 to the first position, as depicted in FIG. 1B. In some embodiments, at least one biasing member 112 may be configured to provide an operating force to at least one plunger 104 to allow an outward, translational movement of at least one plunger 104. In some embodiments, at least one plunger 104 may be positioned in proximity to at least one sensor 108. Further, the translational movement of at least one plunger 104 may facilitate interruption and reflection of the emitted one or more rays to at least one sensor 108 for opening or closing power switch 100.

In some exemplary embodiments, at least one biasing member 112 may be retracted or compressed to store potential energy within at least one biasing member 112 upon application of sufficient external force over at least one plunger 104. The retraction of at least one biasing member 112 may result in the movement of at least one plunger 104 to reach the second position from the first position. Further, upon release of the external force from at least one plunger 104, the at least one biasing member 112 may extend and the stored potential energy trapped within the at least one biasing member 112 may be released. Extension of at least one biasing member 112 may drive at least one plunger 104 back to the first position. The translational movement of at least one plunger 104, may provide an operating force for opening and closing power switch 100. In some exemplary embodiments, the material and design of at least one biasing member 112 may be carefully selected to consider the fatigue resistance and the life span of at least one biasing member 112.

In some embodiments, the translational movement of at least one plunger 104, or the positioning of at least one plunger 104 in the second position, may interrupt the emitted one or more IR signals. Such interruption may cause one or more IR signals to bounce back towards at least one sensor 108 and be received by the receiver. The receiver may further detect the interruption or reflection of the one or more IR signals. Further, based on the interruption, an output response may be triggered in the form of generating one or more signals.

In some embodiments, at least one switching circuit 114 may be electrically coupled with at least one sensor 108. Further, at least one switching circuit 114 may be fabricated on PCB 110. In some embodiments, at least one switching circuit 114 may be responsible for opening and closing power switch 100, based at least on the one or more generated signals from at least one sensor 108. Further, at least one switching circuit 114 may comprise one or more transistors. The one or more transistors upon receiving the one or more signals from at least one sensor 108, may cither open or close power switch 100.

In some example embodiments, the one or more transistors may comprise at least one metal oxide field-effect transistor (MOSFET) for high switching speed. The MOSFET may offer low on-resistance, which lead to minimal power dissipation and heat generation, suitable for handling high voltages and currents. In another example embodiment, the one or more transistors may comprise at least one field-effect transistor (FET) due to minimal gate leakage current, which requires minimum power consumption. In yet another example embodiment, the one or more transistors may comprise at least one insulated-gate bipolar transistor (IGBT). The IGBT may be a combination of a MOSFET with a bipolar junction transistor (BJT) and may include high efficiency and scalability. In yet another example embodiment, the one or more transistors may comprise at least one in-plane switching (IPS) for precise control over power switch 100.

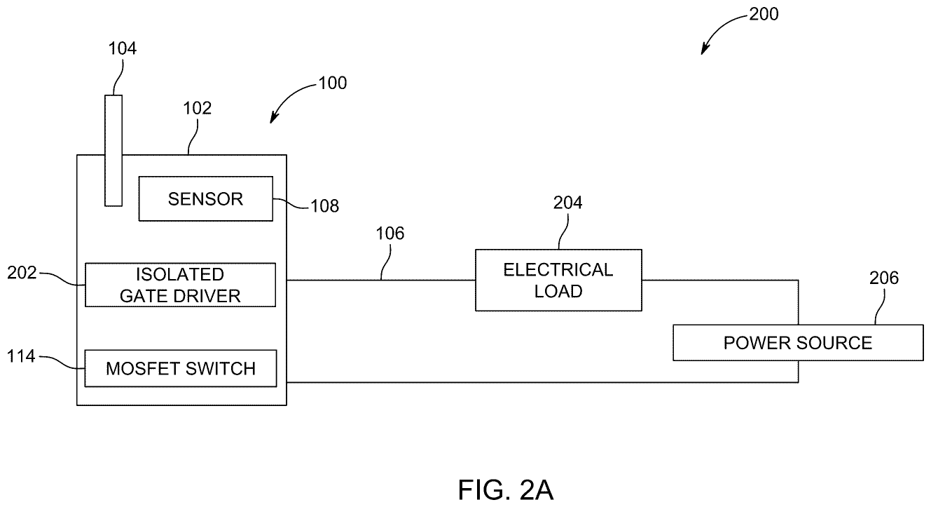

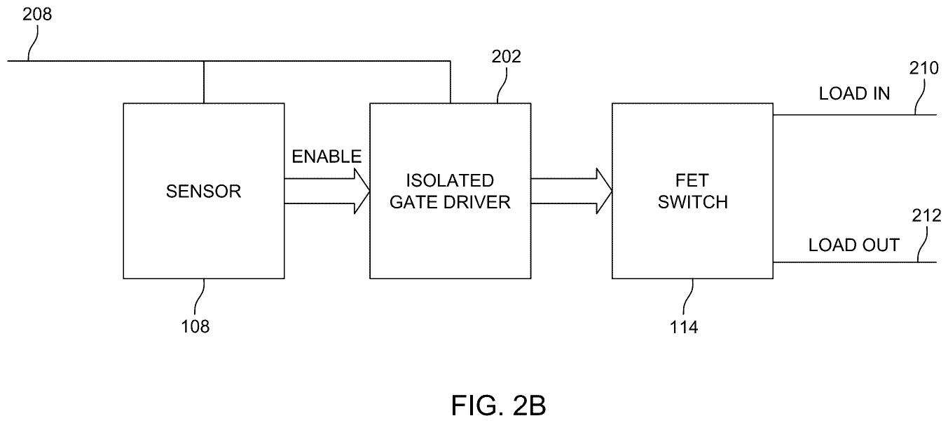

FIG. 2A illustrates a block diagram 200 of power switch 100, in accordance with an example embodiment of the present disclosure. FIG. 2B illustrates an enlarged view of power switch 100, in accordance with an example embodiment of the present disclosure. FIGS. 2A-2B are described in conjunction with FIGS. 1A-1B.

Power switch 100 may comprise at least one isolated gate driver 202, one or more electrical loads 204, and at least one power source 206. At least one isolated gate driver 202 may be configured to receive a low-power output signal from at least one sensor 108. Further, at least one isolated gate driver 202 may modulate the low-power output signal to provide a high-current drive to the gate terminal of the one or more transistors incorporated within at least one switching circuit 114. At least one isolated gate driver 202 may be configured to provide a threshold amount of voltage to at least one switching circuit 114 to change the operational state of the power switch 100 that may be either open or close state of the power switch 100.

In some embodiments, the one or more terminals 106 may be electrically coupled with the at least one switching circuit 114. One or more terminals 106 may be crafted in a manner to couple at least one switching circuit 114 with one or more electrical loads 204 and at least one power source 206.

As illustrated in FIG. 2B, one or more terminals 106 may be classified as an enable terminal 208, a load in terminal 210, and a load out terminal 212. Enable terminal 208 may be connected to at least one isolated gate driver 202. In some embodiments, after successful modulation of the output signals of at least one sensor 108, the enable terminal 208 may supply a threshold amount of voltage to the gate terminal of the one or more transistors that may further actuate power switch 100 by allowing current to flow through load in terminal 210 and load out terminal 212. Further, load in terminal 210 may connect one or more electric loads 204 to at least one power source 206. In some embodiments, activation of the power switch 100 may enable a flow of current from the load in terminal 210 to load out terminal 212, for supplying power to the one or more electrical loads 204. In some exemplary embodiments, the load in terminal 210 and the load out terminal 212, respectively, may handle up to 440 volts (V) and currents less than 1 ampere (A).

In some embodiments, at least one power source 206 may be an alternating current (AC) or direct current (DC) power source for controlling the current flow within one or more electrical loads 204. In some embodiments, at least one sensor 108 and at least one switching circuit 114 may be fabricated over PCB 110. PCB 110 may be constructed by highly conductive materials including at least copper for providing a lower level of electrical resistance among at least one switching circuit 114 and at least one sensor 108.

It will be apparent to one skilled in the art that the above-mentioned components of power switch 100 have been provided only for illustration purposes, without departing from the scope of the disclosure.

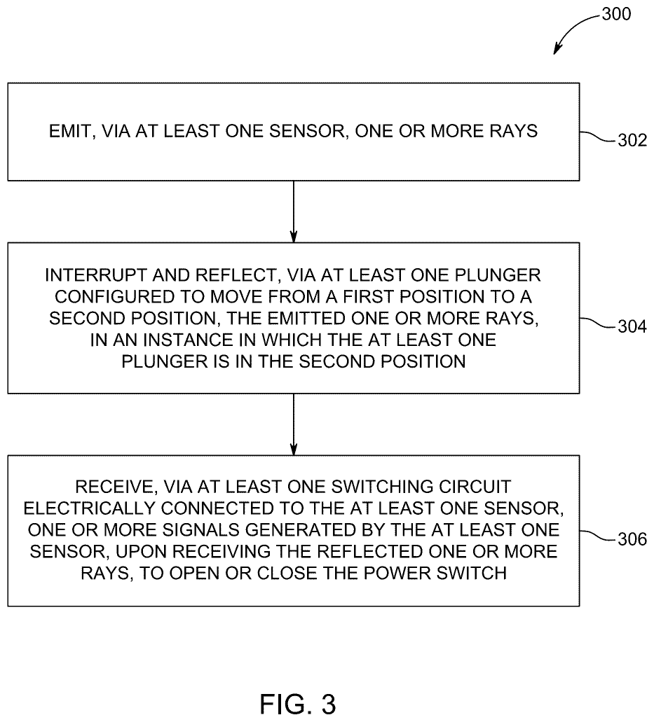

FIG. 3 illustrates a flowchart 300 showing steps of a method for controlling operational states of one or more electrical loads 204 using power switch 100, in accordance with an example embodiment of the present disclosure. FIG. 3 is described in conjunction with FIGS. 1A-2B.

At operation 302, at least one sensor 108 may emit one or more rays. In some embodiments, at least one sensor 108 may comprise the emitter to emit one or more IR signals that may be further received by the receiver integrated on at least one sensor 108.

At operation 304, at least one plunger 104 may interrupt and reflect the emitted one or more rays, in an instance in which at least one plunger 104 is in the second position. In some embodiments, at least one plunger 104 may be positioned in proximity to at least one sensor 108. Further, a force may be applied to at least one plunger 104, that results in providing translational movement to at least one plunger 104 towards at least one sensor 108. At least one plunger 104 may be constructed in a manner to provide a physical barrier to the one or more IR signals. Translational movement of at least one plunger 104 may cause an interruption in one or more IR signals and may further provide the operating force for opening or closing power switch 100.

As discussed earlier, at least one plunger 104 may be coated with the reflective material to reflect or scatter the emitted one or more rays back to at least one sensor 108. In some embodiments, the reflective material may inherit properties that may completely or partially reflect the emitted one or more rays back to the receiver only after application of the external force on at least one plunger 104. Further, in an instance in which at least one plunger 104 is in the second position, at least one plunger 104 may be configured to block or scatter at least a portion of the one or more rays.

At operation 306, at least one switching circuit 114 may receive the one or more signals generated by at least one sensor 108, upon receiving the reflected one or more rays, to open or close power switch 100. In some embodiments, the one or more IR signals are interrupted as the force may be applied on at least one plunger 104 and at least one sensor 108 may detect an IR signal reflection from at least one plunger 104, thereby generating one or more signals. In some embodiments, at least one sensor 108 may comprise one of the photodetector, the IR sensor, or the optical sensor that may emit photodetector rays, IR rays or optical rays, respectively. Further, the physical manipulation caused by at least one plunger 104 may allow at least one sensor 108 to generate the output response based on the generated one or more signals.

In some embodiments, the generated one or more signals may be received by at least one switching circuit 114. Further, at least one switching circuit 114 may interpret the signals to decide whether to open or close power switch 100. At least one switching circuit 114 may further comprise one or more transistors. The one or more transistors may be responsible for opening and closing power switch 100. In some embodiments, one or more transistors may comprise of a metal oxide field-effect transistor (MOSFET), a field-effect transistor (FET), an insulated-gate bipolar transistor (IGBT) or any power switching device known in the art.

In some embodiments, at least one sensor 108 and at least one switching circuit 114 may be electrically coupled via at least one isolated gate driver 202. Further, at least one isolated gate driver 202 may modulate a low-power output signal from at least one sensor 108. At least one isolated gate driver 202 may provide the high-current drive input to the gate terminal of the one or more transistors incorporated within switching circuit 114, respectively. As a result, the current may flow from at least one power source 206 to one or more electrical loads 204.

In some embodiments, one or more terminals 106 may be electrically coupled with at least one switching circuit 114. Further, the one or more terminals 106 may be configured to allow the coupling of at least one switching circuit 114 with one or more electrical loads 204. At least one switching circuit 114 may open or close to activate or deactivate one or more electrical loads 204. The connection of the one or more terminals 106 with at least one switching circuit 114 may allow precise and efficient control over power distribution to the connected one or more electrical loads 204.

In some embodiments, at least one power source 206 may be configured to supply power to one or more electrical loads 204 via at least one switching circuit 114. At least one switching circuit 114 may activate one or more terminals 106 to provide a stable and reliable energy supply to the connected one or more electric loads 204.

The present disclosure may involve the power switch 100 to control one or more electric loads 204 without any direct contact in between power switch 100 and the one or more electrical loads 204. Power switch 100 may further incorporate at least one sensor 108 to send infrared rays that are interrupted by at least one plunger 104 due to an external force application on at least one plunger 104. At least one sensor 108 may further detect signal reflection and generate the one or more signals for at least one switching circuit 114 to open or close power switch 100 as required for supplying power to one or more electrical loads 204 through at least one power source 206.

Many modifications and other embodiments of the disclosure set forth herein will come to mind to one skilled in the art to which the present disclosure pertains, having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A power switch comprising:
at least one sensor configured to emit one or more rays;
at least one plunger configured to move from a first position to a second position, wherein in an instance in which the at least one plunger is in the second position, the at least one plunger is configured to interrupt and reflect back the emitted one or more rays to the at least one sensor; and,
at least one switching circuit electrically connected to the at least one sensor,
wherein the at least one sensor is configured to detect the reflected one or more rays from the at least one plunger to generate one or more signals, and
wherein the at least one switching circuit is configured to open or close the power switch based at least on the generated one or more signals.

2. The power switch of claim 1, wherein in an instance in which the at least one plunger is in the second position, the at least one plunger is configured to block or scatter at least a portion of the one or more rays.

3. The power switch of claim 1, wherein the at least one plunger is positioned over at least one biasing member, and wherein the at least one plunger is coated with a reflective material that is configured to reflect or scatter the emitted one or more rays back to the at least one sensor.

4. The power switch of claim 3, wherein the at least one biasing member is configured to provide an operating force to the at least one plunger to allow translational movement of the at least one plunger.

5. The power switch of claim 4, wherein the at least one plunger is positioned in proximity to the at least one sensor, and wherein the translational movement of the at least one plunger facilitates to interrupt and reflect back the emitted one or more rays to the at least one sensor for opening or closing the power switch.

6. The power switch of claim 1, wherein the at least one sensor comprises at least one of a photodetector, an Infrared (IR) sensor, or an optical sensor.

7. The power switch of claim 1, wherein the at least one switching circuit comprises one or more transistors that upon receiving the one or more signals from the at least one sensor, open or close the power switch.

8. The power switch of claim 7, wherein the one or more transistors comprises at least one of a metal oxide field-effect transistor (MOSFET), a field-effect transistor (FET), or an insulated-gate bipolar transistor (IGBT).

9. The power switch of claim 1, wherein the at least one switching circuit is isolated from one or more electrical loads via at least one isolated gate driver to keep the power switch separated from the one or more electrical loads, wherein at least one power source is configured to supply power to the one or more electrical loads.

10. The power switch of claim 1, wherein the at least one sensor and the at least one switching circuit are fabricated over a printed circuit board (PCB).

11. A method comprising:
emitting, via at least one sensor, one or more rays;
interrupting and reflecting, via at least one plunger configured to move from a first position to a second position, the emitted one or more rays, in an instance in which the at least one plunger is in the second position; and,
receiving, via at least one switching circuit electrically connected to the at least one sensor, one or more signals generated by the at least one sensor, upon receiving the reflected one or more rays, to open or close the power switch.

12. The method of claim 11, wherein in an instance in which the at least one plunger is in the second position, the at least one plunger is configured to block or scatter at least a portion of the one or more rays.

13. The method of claim 11, wherein the at least one plunger is positioned over at least one biasing member, and wherein the at least one plunger is coated with a reflective material that is configured to reflect or scatter the emitted one or more rays back to the at least one sensor.

14. The method of claim 13, wherein the at least one biasing member is configured to provide an operating force to the at least one plunger to allow translational movement of the at least one plunger.

15. The method of claim 11, wherein the at least one plunger is positioned in proximity to the at least one sensor.

16. The method of claim 14, wherein the translational movement of the at least one plunger facilitates to interrupt and reflect back the emitted one or more rays to the at least one sensor for opening or closing the power switch.

17. The method of claim 11, wherein the at least one sensor comprises at least one of a photodetector, an Infrared (IR) sensor, or an optical sensor.

18. The method of claim 11, wherein the at least one switching circuit comprises one or more transistors that upon receiving the one or more signals from the at least one sensor, open or close the power switch.

19. The method of claim 18, wherein the one or more transistors comprises at least one of a metal oxide field-effect transistor (MOSFET), a field-effect transistor (FET), or an insulated-gate bipolar transistor (IGBT).

20. The method of claim 11, wherein the at least one switching circuit is isolated from one or more electrical loads via at least one isolated gate driver to keep the power switch separated from the one or more electrical loads, wherein at least one power source is configured to supply power to the one or more electrical loads.
